(19) United States
(12) Patent Application Publication
(10) Pub. No.: US 2024/0429039 A1
(43) Pub. Date: Dec. 26, 2024

(54) METHOD OF DEPOSITING FILM

(71) Applicant: Samsung Electronics Co., Ltd., Suwon-si (KR)

(72) Inventors: Eun Hyea Ko, Suwon-si (KR); Soyoung Lee, Suwon-si (KR); Hoon Han, Suwon-si (KR); Byungkeun Hwang, Suwon-si (KR); Jaewoon Kim, Suwon-si (KR); Younghun Sung, Suwon-si (KR); Younjoung Cho, Suwon-si (KR)

(21) Appl. No.: 18/597,101

(22) Filed: Mar. 6, 2024

(30) Foreign Application Priority Data
Jun. 22, 2023 (KR) 10-2023-0080582

(51) Int. Cl. H01L 21/02; C09D 5/00; C09D 5/26; C09D 175/02; C23C 16/56; H01L 21/285; H01L 21/3105

(52) U.S. Cl. CPC H01L 21/02118; C09D 5/008; C09D 5/26; C09D 175/02; C23C 16/56; H01L 21/28562; H01L 21/31058

(57) ABSTRACT

Methods of depositing a film are provided. The methods may include providing a substrate that includes a first surface and a second surface adjacent to the first surface; forming a polymer sacrificial layer on the first surface by using a molecular layer deposition (MLD) process; forming a first film on the second surface; and removing the polymer sacrificial layer formed on the first surface. A functional group density of the first surface may be higher than a functional group density of the second surface, and the polymer sacrificial layer may include a thermally decomposable polymer.

### CROSS-REFERENCE TO RELATED APPLICATION

This application claims priority to Korean Patent Application No. 10-2023-0080582 filed in the Korean Intellectual Property Office on Jun. 22, 2023, the disclosure of which is incorporated herein by reference in its entirety.

### BACKGROUND

The present disclosure relates to a method of depositing a film.

According to a high performance of semiconductor devices, the integration of the semiconductor devices is increasing and the semiconductor process is being miniaturized. The integration of the semiconductor devices may be highly dependent on a patterning process.

Therefore, there is a demand for a development of a technology that can easily implement a fine pattern by performing a patterning process in an economical method while simplifying the process of the semiconductor device.

### SUMMARY

Embodiments are intended to provide a film deposition method capable of selectively forming a thick polymer film on a surface having a high functional group density without a separate pretreatment process. A method of depositing a film according to some embodiments of the present invention may include providing a substrate that includes a first surface and a second surface located adjacent to the first surface; forming a polymer sacrificial layer on the first surface by using a molecular layer deposition (MLD) process; forming a first film on the second surface; and removing the polymer sacrificial layer formed on the first surface, wherein a functional group density of the first surface is higher than a functional group density of the second surface, and the polymer sacrificial layer includes a thermally decomposable polymer.

A method of depositing a film according to some embodiments of the present invention may include providing a substrate that includes a first surface and a second surface located adjacent to the first surface; forming a polymer sacrificial layer on the first surface by using a molecular layer deposition (MLD) process; forming a first film on the second surface; removing the polymer sacrificial layer formed on the first surface; forming a second film on the first surface; and removing the first film formed on the second surface, wherein a functional group density of the first surface is higher than a functional group density of the second surface, and the polymer sacrificial layer includes a thermally decomposable polymer.

A method of depositing a film according to some embodiments of the present invention may include providing a substrate that includes a first surface including —OH or —NHx functional groups, and a second surface located adjacent to the first surface and including no functional groups or fewer —OH or —NHx functional groups than the first surface; forming a polymer sacrificial layer including a thermally decomposable polymer on the first surface by using a molecular layer deposition (MLD) process; forming a first film on the second surface; and removing the polymer sacrificial layer formed on the first surface, wherein the forming of the polymer sacrificial layer includes depositing a precursor for forming the polymer sacrificial layer on the substrate to form a preliminary polymer sacrificial layer on the first surface and the second surface; and removing a portion of the preliminary polymer sacrificial layer formed on the second surface by heat treatment, and the precursor includes an electrophile and a compound that reacts with the electrophile to form the thermally decomposable polymer.

According to some embodiments of the present invention, by using the difference in the density of functional groups of surfaces and a molecular layer deposition (MLD) process, a polymer film having a desired thickness may be formed selectively on the surface without a separate pretreatment process.

In addition, in the case of using the methods of depositing a film according to some embodiments of the present invention, a process cost may be reduced, a manufacturing time may be shortened, and high-quality patterns may be effectively formed by simplifying the fine pattern forming process.

The various yet beneficial merits and effects of the present invention are not limited to the above, and will be more easily understood with example embodiments provided herein.

### BRIEF DESCRIPTION OF DRAWINGS

FIG. 1 is a view schematically showing a film deposition method according to some embodiments of the present invention.

FIG. 2 is a graph showing a result of measuring a water contact angle for a first surface and a second surface.

FIG. 3 is a graph showing a result of measuring a thickness of a polyurea-containing film formed on a first surface and a second surface according to the number of cycles in a deposition using an MLD process.

FIG. 4 shows a result of a FT-IR measurement after forming a film including polyurea by using an MLD process on a first surface and a second surface.

FIG. 5 and FIG. 6 show a result of a FT-IR measurement after forming a film including polyurea on a first surface by using a Chemical Vapor Deposition (CVD) process and forming a film including polyurea on a second surface by using an MLD process, respectively.

FIG. 7 shows a result of measuring a thickness of a film including polyurea for each deposition temperature in a process of depositing a film by using an MLD process.

FIG. 8 is a view schematically showing a film deposition method according to some embodiments of the present invention.

### DETAILED DESCRIPTION

The present invention will be described more fully hereinafter with reference to the accompanying drawings, in which some example embodiments of the present invention are shown. As those skilled in the art would realize, the described embodiments may be modified in various different ways, all without departing from the scope of the present invention.

In order to clarify the present invention, parts that are not connected with the description will be omitted, and the same elements or equivalents are referred to by the same reference numerals throughout the specification.

Further, since sizes and thicknesses of constituent members shown in the accompanying drawings are arbitrarily given for better understanding and ease of description, the present invention is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means located on or below the object portion and does not necessarily mean located on the upper side of the object portion based on a gravitational direction.

In addition, unless explicitly described to the contrary, “comprise” and “include” and variations thereof such as “comprises,” “comprising,” or “including” will be understood to imply the inclusion of stated elements but not the exclusion of any other elements.

Further, in the specification, the phrase “on a plane” means when an object portion is viewed from above, and the phrase “on a cross-section” means when a cross-section taken by vertically cutting an object portion is viewed from the side.

A method of depositing a film according to some embodiments of the present invention may include providing a substrate that includes a first surface and a second surface located adjacent to the first surface; forming a polymer sacrificial layer on the first surface by using a molecular layer deposition (MLD) process; forming a first film on the second surface; and removing the polymer sacrificial layer formed on the first surface. In some embodiments, the polymer sacrificial layer formed on the first surface may be removed after the first film is formed on the second surface.

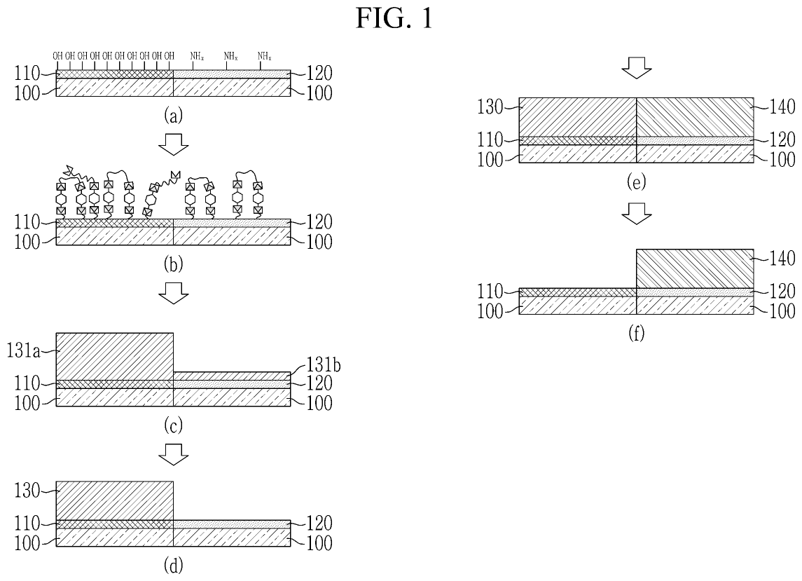

FIG. 1 is a view schematically showing a method of depositing a film according to some embodiments of the present invention.

Referring to FIG. 1(a), a substrate 100 that includes a first surface 110 and a second surface 120 located adjacent to the first surface 110 is provided. In some embodiments, each of the first surface 110 and the second surface 120 may be a portion of the substrate 100 (e.g., a portion of a surface of the substrate 100) or may be a portion of a layer or a film formed on the substrate 100 (e.g., a surface of a layer or a film formed on the substrate 100). In some embodiments, the first surface 110 and the second surface 120 may be directly connected to each other as illustrated in FIG. 1(a).

The substrate 100 may include, for example, a dielectric material. The dielectric material may include, for example, a low-k dielectric material, SiO₂, or a metal-including dielectric material.

At this time, a functional group density of the first surface 110 is higher than a functional group density of the second surface 120. For example, the functional group on the first and second surfaces 110 and 120 may be a hydroxy group and/or an amine group. In detail, the first surface 110 includes, for example, a functional group of —OH or —NHx. The first surface 110 may include, for example, silicon nitride, silicon oxide and/or silicon.

In addition, the second surface 120 does not include a functional group or includes less of the functional groups of —OH or —NHx than the first surface 110. For example, the second surface 120 is devoid of the —OH or —NHx functional group or comprises 10%, 20%, 30%, 40%, 50%, 60%, 70%, 80%, 90%, 95% fewer functional groups of —OH or —NHx than the first surface 110. The second surface 120 may be, for example, at least one of a metal, a metal oxide, a metal nitride, and an organic layer in which the functional groups are not substantially exposed on the surface.

The metal may include, for example, copper (Cu), ruthenium (Ru), cobalt (Co), or tungsten (W). The metal oxide may include, for example, zirconium oxide, hafnium oxide, aluminum oxide, titanium oxide, tantalum oxide, yttrium oxide, lanthanum oxide, or other transition metal oxides or mixtures thereof. The metal nitride may be, for example, titanium nitride.

The organic layer in which the functional groups are not substantially exposed on the surface may be, for example, a photoresist layer or a BARC (Bottom Anti-Reflection Coating) resin.

Next, a polymer sacrificial layer 130 is formed on the first surface 110 by using a molecular layer deposition (MLD) process.

The polymer sacrificial layer 130 may include a thermally decomposable polymer.

For example, the thermally decomposable polymer may be decomposable at a temperature of 150° C. or higher. Specifically, the thermally decomposable polymer may include, for example, polyurea and/or a carbamate, but the thermally decomposable polymer is not limited thereto.

The forming of the polymer sacrificial layer 130 may include forming preliminary polymer sacrificial layers 131a and 131b on the first surface 110 and second surface 120 by supplying a precursor for forming the polymer sacrificial layer 130 on the substrate 100, and heat treating the preliminary polymer sacrificial layer 131b formed on the second surface 120 to be removed. A portion of the preliminary polymer sacrificial layer 131b formed on the second surface 120 may be removed by a heat treatment process (e.g., an annealing process).

The precursor for forming a polymer sacrificial layer may include a monomer having a high flexibility.

When using a monomer with low flexibility as a precursor, it may be difficult to selectively form a film only on the desired surface. In addition, when the density of the surface functional group is low, the reactivity may be low, so it may be difficult to form a thick film even using a molecular layer deposition process.

Therefore, since the precursor including the monomer with high flexibility and at the same time the functional group density of the first surface 110 is higher than that of the second surface 120, it may be possible to selectively form a polymer film with a thick thickness only on the first surface 110 by using a molecular layer deposition process.

Specifically, the supplying of the precursor may be performed by alternately supplying an electrophile and a compound that reacts with the electrophile to form the thermally decomposable polymer. In some embodiments, the supplying of the precursor may include multiple cycles, each of which may include supplying an electrophile and then subsequently supplying a compound that reacts with the electrophile to form the thermally decomposable polymer.

The electrophile may include, for example, ethylene diisocyanate, trimethylene diisocyanate, tetramethylene diisocyanate, pentamethylene diisocyanate, hexamethylene diisocyanate, heptamethylene diisocyanate, octamethylene diisocyanate, phenyl diisocyanate, diphenylmethane 4,4′-diisocyanate and/or 4,4,4″-triphenylmethane triisocyanate, but the electrophile is not limited thereto.

In addition, the compound that reacts with the electrophile to form the thermally decomposable polymer may include, for example, an amine including two or more amine moieties, a diol and/or a dithiol.

In detail, the amine including two or more amine moieties may include, for example, diamine, triamine, tetraamine, pentamine, cyclic amine, cyclic diamine, amine oligomer, polyamine and/or alcohol amine, but the amine is not limited thereto.

Next, the polyamine may include, for example, ethylenediamine, trimethylenediamine, tetramethylenediamine, pentamethylenediamine, hexamethylenediamine, heptamethylenediamine, octamethylenediamine, diethylene triamine, benzene triamine, triethylenetetraamine, diethylenetriamine, melamine, hexaaminobenzene, polyethyleneimine and/or N,N′-dimethylethylenediamine, but the polyamine is not limited thereto.

In some embodiments, the molecular layer deposition is a method in which two or more molecules are alternately supplied to form a molecular layer through a precise chemical bonding, and it is possible to form a molecular layer with a high degree of an alignment. Molecular layer deposition (MLD) process may entirely form a uniform thin film of the aligned form over the entire surface, not only on a flat surface, but also on the substrate 100 on which patterns are formed. A thin film formed by an MLD process may have very stable characteristics, because a substrate and molecules are connected by strong chemical bonds, and molecules and molecules are also connected by strong chemical bonds. In addition, since the molecular layer deposition process deposits the molecular layers layer by layer on the desired surface, it is possible to form the polymer thin film with the uniform thickness.

For example, the process of forming the preliminary polymer sacrificial layers 131a and 131b is carried out by a method in which an electrophile and a compound that reacts with the electrophile to form the thermally decomposable polymer are alternately supplied into a chamber where the molecular layer deposition is performed. First, the electrophile is supplied and bound onto the first surface 110 and the second surface 120, and the unbound reactant is removed. Next, the compound that reacts with the electrophile to form the thermally decomposable polymer is supplied, and one thermally decomposable molecular layer is formed on the first surface 110 and second surface 120, and this process corresponds to a single cycle. By repeating the cycle, the polymer film having a desired thickness may be formed. In addition, the speed at which the molecular layer is deposited may be controlled within a desired range by controlling a time of an implantation of precursors into the chamber and an implant amount.

For example, if diisocyanate is first supplied, then diamine and diisocyanate are repeatedly supplied, since a film formed on the first surface 110 having a high functional group density still includes functional groups, a molecular layer is continuously deposited, thereby forming a polymer film including polyurea.

On the other hand, in the polymer film formed on the second surface 120 having a low functional group density, it is difficult to form a thick polymer film because the reaction is self-terminated. Therefore, when using the method of depositing the film according to some embodiments, the thick polymer film may be selectively formed only on the first surface 110 having a high functional group density.

As above-described, when using molecular layer deposition, since the thickness of the thin film deposited per a cycle is uniform on the first surface 110, it is possible to control the thickness of the desired thin film on a nano scale by adjusting the number of the deposition cycles. In addition, since the thin film is deposited on the surface through a self-limiting reaction in which the deposition is performed by one molecular layer, the polymer thin film with excellent thickness uniformity may be deposited. In addition, the functional groups formed on the surface of the formed film are uniformly aligned, and by adjusting the type of a chemical bond with the precursor, it is possible to have a desired functional group on the surface of the polymer thin film, so that the surface characteristics of the polymer thin film may be easily controlled.

On the other hand, the high functional group density of the first surface 110 means that the density of the reaction site is high, as shown in FIG. 1(b). The second surface 120 has a lower reaction site density than the first surface 110. Using this difference in the density of the functional group, the thick film can be selectively formed only on the first surface 110 without a separate pretreatment process.

When preliminary polymer sacrificial layers 131a and 131b are formed on the first surface 110 and the second surface 120 by using the molecular layer deposition, as shown in FIG. 1 (c), the thick preliminary polymer sacrificial layer 131a is formed on the first surface 110 having the high functional group density, and the relatively thin preliminary polymer sacrificial layer 131b is formed on the second surface 120 having the low functional group density.

The thickness of the preliminary polymer sacrificial layer 131a formed on the first surface 110 is thicker than the thickness of the preliminary polymer sacrificial layer 131b formed on the second surface 120, for example, the thickness of the preliminary polymer sacrificial layer 131a formed on the first surface 110 may range from 1.5 times to 10 times of the thickness of the preliminary polymer sacrificial layer 131b formed on the second surface 120.

Next, when the substrate 100 on which the preliminary polymer sacrificial layers 131a and 131b are formed is heat treated for a short time, the preliminary polymer sacrificial layer 131b formed on the second surface 120 may be removed, as shown FIG. 1(d), and the substrate 100 in which the polymer sacrificial layer 130 is formed only on the first surface 110 may be manufactured.

Heat treatment (also referred to as a heat treatment process) to remove the preliminary polymer sacrificial layer 131b formed on the second surface 120 may be performed at a temperature of, for example, 150° C. or higher (e.g., 150° C., 155° C., 160° C., 165° C., 170° C., 175° C., 180° C., 185° C., 190° C. or higher).

Next, referring to FIG. 1(e), a step of forming a first film 140 on the second surface 120 is performed.

The first film 140 may include, for example, a metal element. Specifically, the first film may include, for example, zirconium oxide, hafnium oxide, aluminum oxide, titanium nitride and/or titanium oxide.

Thereafter, referring to FIG. 1(f), removing the polymer sacrificial layer 130 formed on the first surface 110 is performed.

The removing the polymer sacrificial layer 130 formed on the first surface 110 is performed using a heat treatment process.

Heat treatment to remove the polymer sacrificial layer 130 formed on the first surface 110 may be performed at a temperature of, for example, 150° C. or higher (e.g., 150° C., 155° C., 160° C., 165° C., 170° C., 175° C., 180° C., 185° C., 190° C. or higher).

In addition, the heat treatment for removing the polymer sacrificial layer 130 formed on the first surface 110 may be performed for a longer time than the heat treatment for removing the preliminary polymer sacrificial layer 131b formed on the second surface 120. This is because the polymer sacrificial layer 130 formed on the first surface 110 is formed to have the thick thickness, but the preliminary polymer sacrificial layer 131b formed on the second surface 120 has the relatively very thin thickness.

The methods of depositing the film according to some embodiments may be usefully applied in the semiconductor manufacturing process.

For example, when a fully self-aligned via (FSV) structure is to be implemented in a back end of line (BEOL), there is a case that a film including a dielectric material may be selectively used as a sacrificial layer.

Specifically, when patterning a via with a very small pitch in the semiconductor manufacturing process, a perfect alignment is difficult with a photoresist process. Therefore, in this case, an edge placement error (EPE) inevitably occurs, which deteriorates the yield of the semiconductor manufacturing process.

One of the alternatives that can reduce or prevent edge placement errors is a technology that may form a sacrificial layer whose thickness may be adjusted on a surface including a dielectric material. In this way, by forming the sacrificial layer capable of selectively adjusting the thickness on the surface, it is possible to increase an interval between vias and, consequently, to reduce or prevent a short circuit from occurring within a product.

In addition, it is difficult to form a second layer after forming the first layer for most surface-selective sacrificial layers. Therefore, in this case, when a desired film is formed using the sacrificial layer, a mushroom growth in which an upper part of the film grows laterally may occur. However, when applying the method of depositing the film according to some embodiments, the thickness of the sacrificial layer formed on the surface including the dielectric material may be adjusted to the desired range by the method of combining appropriate precursors by using a molecular layer deposition process and adjusting the number of the cycles, and by using this, it may be possible to reduce or prevent the film to be formed from growing in a mushroom shape.

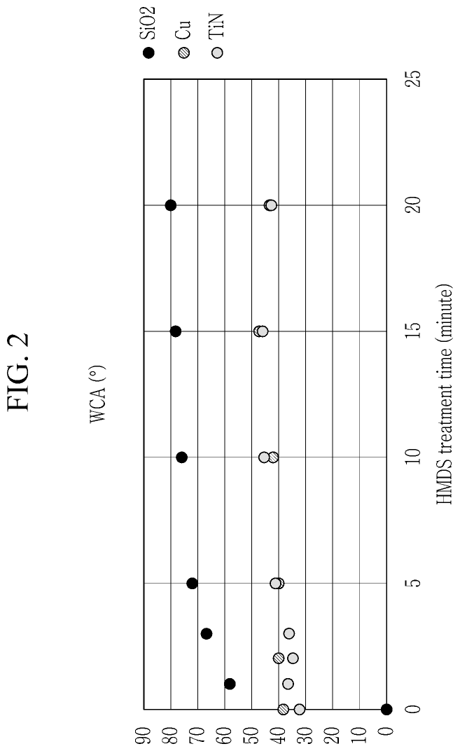

FIG. 2 is a graph showing a result of measuring a water contact angle for a first surface and a second surface.

Specifically, in order to compare the density of each reaction site, a water contact angle was measured by a method of measuring an angle formed with the surface by dropping a water while depositing hexamethyldisilazane, which is known to be capable of reacting with —OH and —NHx by using equipment.

In the measurement, SiO₂ was used as the first surface material, and Cu or TiN was used as the second surface material.

Referring to FIG. 2, it may be seen that the Cu or TiN surface is measured at a point where the water contact angle is lower than that of SiO₂. That is, it may be seen that there are a lot of functional groups that may react on the SiO₂ surface, and the surface of the film formed while these functional groups react with hexamethyldisilazane gradually appears hydrophobic, and then the water contact angle increases. As a result, it may be seen that the density of the functional groups that can react on the surface is much higher in the first surface.

Next, a film including polyurea was deposited on the first surface and the second surface by a method of alternately and repeatedly supplying diisocyanate and diamine by using an MLD process.

At this time, SiO₂ was used as the first surface material, and TiN or an organic layer was used as the second surface material.

In a deposition using an MLD process, the water contact angle for the film including polyurea was measured for each number of cycles and is shown in Table 1 below.

TABLE 1

Water Contact Angle (°)

| | | | |
|---|---|---|---|
| Cycle | | | On Organic |
| number | On Native Ox | On TiN | Layer |

| | | | | |
|---|---|---|---|---|
| 0 | cycle | 9 | 32.3 | 50.5 |
| 650 | cycle | 67.4 | 72.9 | 60.7 |
| 3250 | cycle | — | 69.8 | 60.6 |

Referring to Table 1, it may be confirmed that the water contact angle of the film including polyurea formed on the first surface increases as the MLD process is repeated.

However, for the film including polyurea formed on the second surface containing TiN, the water contact angle increased by about 2 times, for film including polyurea formed on the second surface including an organic layer, little change showed in the water contact angle. Through this, it may be confirmed that the film including polyurea was formed on the first surface and the second surface including TiN.

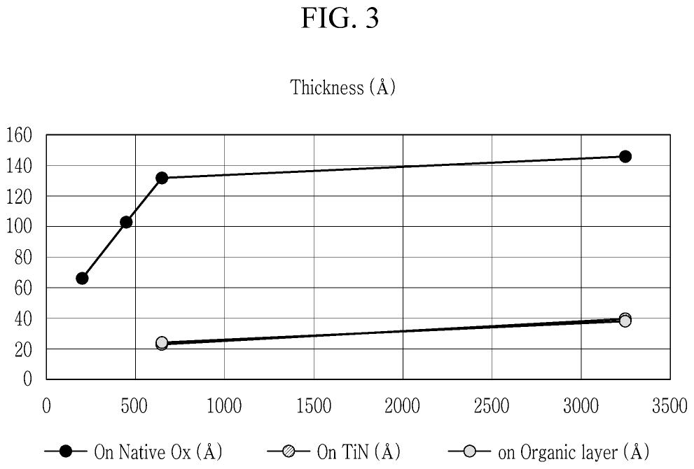

FIG. 3 is a graph showing a result of measuring a thickness of a polyurea-including film formed on a first surface and a second surface according to the number of cycles in a deposition using an MLD process.

Referring to FIG. 3, a film including polyurea can be grown thickly on the first surface, but the film growth was confirmed on TiN or an organic layer, but the thickness is very thin.

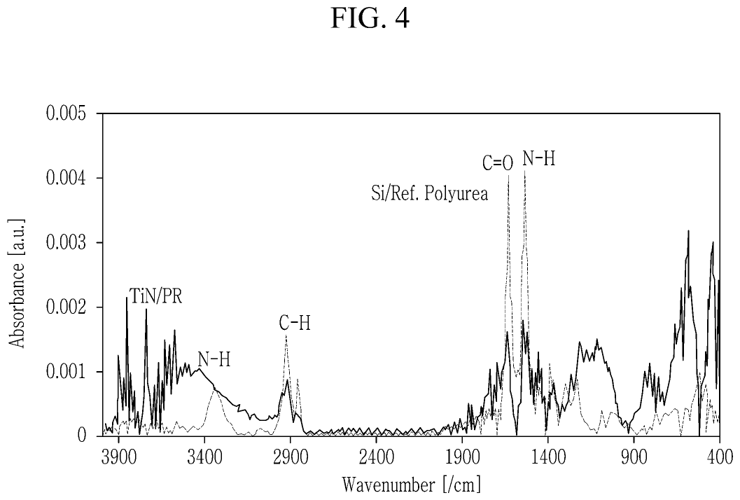

FIG. 4 shows a result of a FT-IR measurement after forming a film including polyurea by using an MLD process on a first surface and a second surface. At this time, SiO₂ was used as the first surface and an organic layer was used as the second surface.

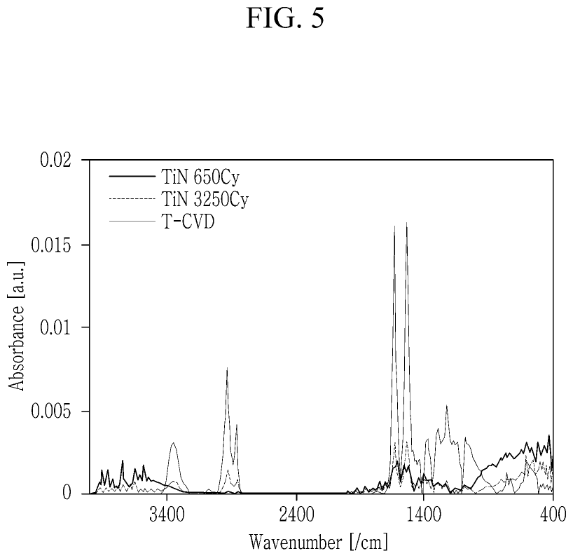

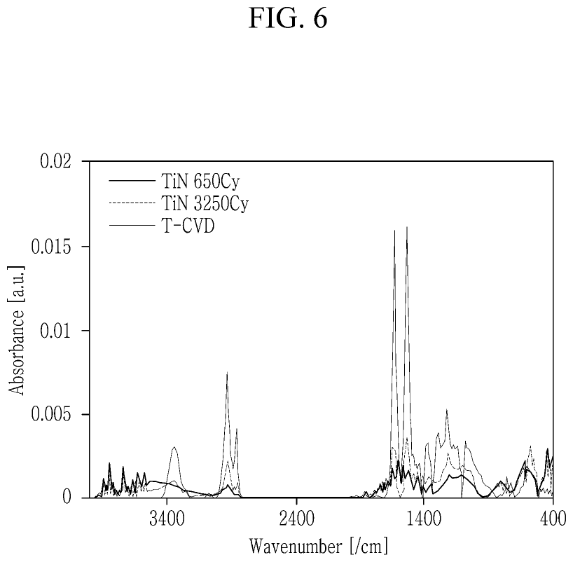

FIG. 5 and FIG. 6 show a result of a FT-IR measurement after forming a film including polyurea on a first surface by using CVD and forming a film including polyurea on a second surface by using an MLD process, respectively.

In this case, FIG. 5 is a case where SiO₂ is used as the first surface and TiN is used as the second surface. FIG. 6 is a case where SiO₂ is used as the first surface and TiN is used as the second surface. Also, in FIG. 5 and FIG. 6, the MLD process was performed 650 times and 3250 times for the second surface.

Referring to FIG. 4 to FIG. 6, on the surface including SiO₂, even when being deposited by the MLD process, it was confirmed that the IR peak was consistent with the case of being deposited by the CVD method, and the IR peak was sharp, as a result, it may be seen that the film including polyurea is well formed even when using the MLD process.

On the other hand, when being deposited by the MLD process on the surface including TiN or an organic layer by, the film including polyurea was formed, but it may be seen that the IR peak is generally small and difficult to distinguish.

Through this, it may be confirmed that when the film including polyurea is deposited by using the MLD process on the second surface where there is no functional group or the density of the functional group is low, it is formed with a very thin thickness. This is consistent with the result of FIG. 3.

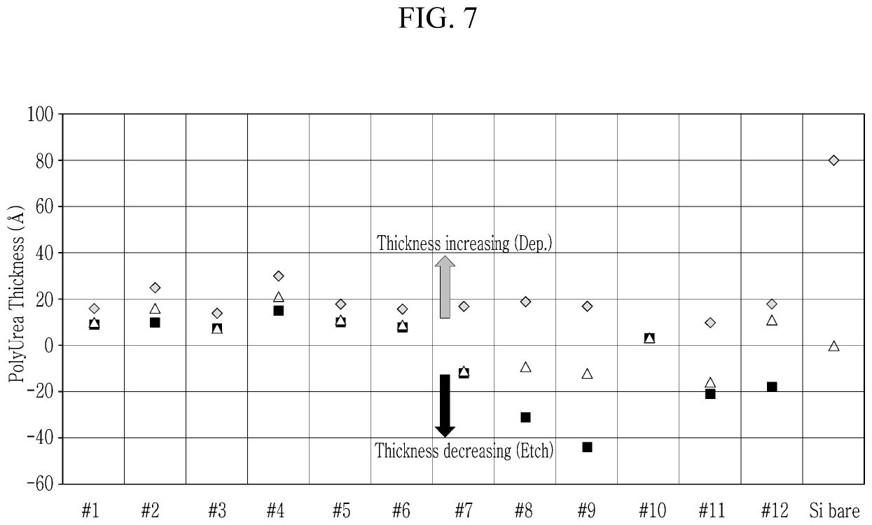

Next, FIG. 7 and Table 2 are provided to show a result of measuring a thickness of a film including polyurea for each deposition temperature in a process of depositing a film by using MLD process.

In FIG. 7, #1 to #6 are cases where a film including polyurea is deposited after forming a TiN surface on a silicon substrate, #7 to #12 are cases in which a TiN surface is formed on a silicon substrate, a photoresist layer is formed thereon, and a film including polyurea is deposited, and Si bare is a case where a film including polyurea on a silicon substrate.

TABLE 2

| Deposition | | | | | | | | | | | | | |
|---|---|---|---|---|---|---|---|---|---|---|---|---|---|
| temperature | Thickness of film including polyurea (angstroms) | | | | | | | | | | | | |
| (° C.) | #1 | #2 | #3 | #4 | #5 | #6 | #7 | #8 | #9 | #10 | #11 | #12 | Si bare |
| 90 | 16 | 25 | 14 | 30 | 18 | 16 | 17 | 19 | 17 | — | 10 | 18 | 80 |
| 150 | 10 | 16 | 7 | 21 | 11 | 9 | −12 | −9 | −12 | 3 | −16 | 11 | 0 |
| 200 | 9 | 10 | 7 | 15 | 10 | 8 | −12 | −31 | −44 | 3 | −21 | −18 | 0 |

Referring to Table 2 and FIG. 7, it may be confirmed that the film including polyurea formed using an MLD process is generally well formed at 90° C.

However, at 150° C. or higher, it may be seen that the film including polyurea is not deposited on both the photoresist layer and the silicon substrate, and even on the surface including TiN. When the temperature is 150° C., it may be seen that the deposition does not work well.

As a result, it may be seen that the appropriate deposition temperature of the film including polyurea using an MLD process ranges from 20° C. to 150° C.

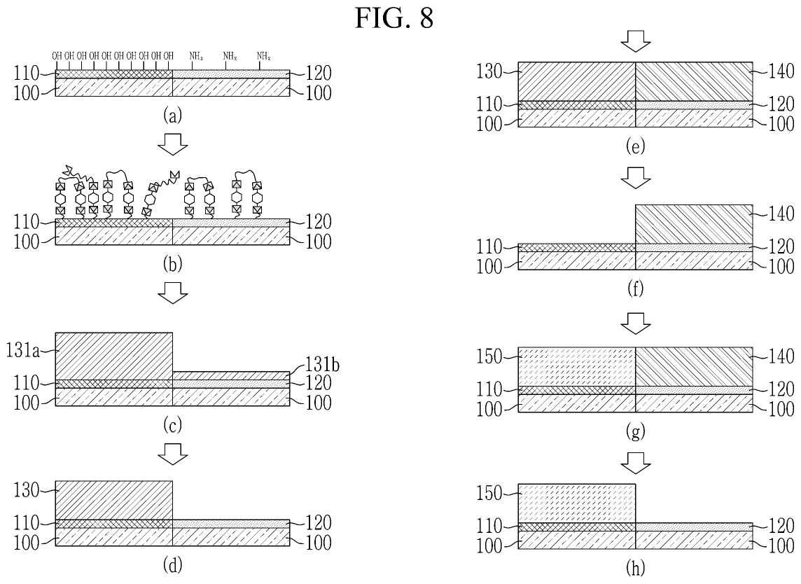

FIG. 8 is a view schematically showing a film deposition method according to some embodiments of the present invention.

A method of depositing a film according to some embodiments of the present invention may include providing a substrate that includes a first surface 110 and a second surface located adjacent to the first surface 110; forming on a polymer sacrificial layer 130 on the first surface 110 by using a molecular layer deposition (MLD) process; forming a first film on the second surface; removing a polymer sacrificial layer 130 formed on the first surface 110; forming a second film on the first surface 110; and removing the first film formed on the second surface.

In this case, the functional group density of the first surface 110 is higher than that of the second surface 120, and the polymer sacrificial layer 130 may include a thermally decomposable polymer.

FIG. 8(a) to FIG. 8(f) are the same as those described with reference to FIG. 1, so the detailed description is omitted here.

In some embodiments, the first film 140 formed on the second surface 120 may be used as a sacrificial layer. Accordingly, as shown in FIG. 8(g), after performing the process of forming the second film 150 on the first surface 110, as shown in FIG. 8(h), the process of removing the first film 140 formed on the second surface 120 is performed.

Here, the second film 150 may include, for example, the same material as the first surface 110. The second film may include, for example, SiCN and/or SiOC.

Accordingly, it is possible to form the film including the dielectric material on the surface including the dielectric material.

As used herein, the term “and/or” includes any and all combinations of one or more of the associated listed items.

While this disclosure has been described in connection with some example embodiments, it is to be understood that the invention is not limited to those embodiments. On the contrary, it is intended to cover various modifications and equivalent arrangements included within the scope of the appended claims.

What is claimed is:

1. A method of depositing a film comprising:
providing a substrate that includes a first surface and a second surface adjacent to the first surface;
forming a polymer sacrificial layer on the first surface by using a molecular layer deposition (MLD) process;
forming a first film on the second surface; and
removing the polymer sacrificial layer formed on the first surface,
wherein a functional group density of the first surface is higher than a functional group density of the second surface, and
the polymer sacrificial layer includes a thermally decomposable polymer.

2. The method of depositing the film of claim 1, wherein the forming of the polymer sacrificial layer includes:
supplying a precursor for forming the polymer sacrificial layer on the substrate to form a preliminary polymer sacrificial layer on the first surface and the second surface; and
removing a portion of the preliminary polymer sacrificial layer formed on the second surface by heat treatment.

3. The method of depositing the film of claim 2, wherein a thickness of a portion of the preliminary polymer sacrificial layer formed on the first surface is thicker than a thickness of the portion of the preliminary polymer sacrificial layer formed on the second surface.

4. The method of depositing the film of claim 2, wherein a thickness of a portion of the preliminary polymer sacrificial layer formed on the first surface ranges from 1.5 times to 10 times of a thickness of the portion of the preliminary polymer sacrificial layer formed on the second surface.

5. The method of depositing the film of claim 2, wherein the supplying of the precursor is performed by alternately supplying an electrophile and a compound that reacts with the electrophile to form the thermally decomposable polymer.

6. The method of depositing the film of claim 5, wherein the electrophile includes ethylene diisocyanate, trimethylene diisocyanate, tetramethylene diisocyanate, pentamethylene diisocyanate, hexamethylene diisocyanate, heptamethylene diisocyanate, octamethylene diisocyanate, phenyl diisocyanate, diphenylmethane 4,4′-diisocyanate and/or 4,4,4″-Triphenylmethane triisocyanate.

7. The method of depositing the film of claim 5, wherein the compound that reacts with the electrophile to form the thermally decomposable polymer includes an amine including two or more amine moieties, a diol and/or a dithiol.

8. The method of depositing the film of claim 7, wherein the amine including two or more amine moieties includes diamine, triamine, tetraamine, pentaamine, cyclic amine, cyclic diamine, amine oligomer, polyamine and/or alcohol amine.

9. The method of depositing the film of claim 8, wherein the polyamine includes ethylenediamine, trimethylenediamine, tetramethylenediamine, pentamethylenediamine, hexamethylenediamine, heptamethylenediamine, octamethylenediamine, diethylene triamine, benzene triamine, triethylenetetraamine, diethylenetriamine, melamine, hexaaminobenzene, polyethyleneimine and/or N,N′-dimethylethylenediamine.

10. The method of depositing the film of claim 1, wherein the thermally decomposable polymer includes polyurea and/or a carbamate.

11. The method of depositing the film of claim 1, wherein the thermally decomposable polymer is decomposable at a temperature of 150° C. or higher.

12. The method of depositing the film of claim 1, wherein the forming of the polymer sacrificial layer is performed at a temperature in a range of from 20° C. to 150° C.

13. The method of depositing the film of claim 3, wherein the removing of the polymer sacrificial layer formed on the first surface is performed using heat treatment.

14. The method of depositing the film of claim 13, wherein the heat treatment to remove the polymer sacrificial layer formed on the first surface is performed for a longer time than the heat treatment to remove the portion of the preliminary polymer sacrificial layer formed on the second surface.

15. The method of depositing the film of claim 1, wherein the first surface includes —OH or —NHx functional group.

16. The method of depositing the film of claim 15, wherein the second surface includes no functional group or includes fewer —OH or —NHx functional group than the first surface.

17. A method of depositing a film comprising:
providing a substrate that includes a first surface and a second surface adjacent to the first surface;
forming a polymer sacrificial layer on the first surface by using a molecular layer deposition (MLD) process;
forming a first film on the second surface;
removing the polymer sacrificial layer formed on the first surface;
forming a second film on the first surface; and
removing the first film formed on the second surface,
wherein a functional group density of the first surface is higher than a functional group density of the second surface, and
the polymer sacrificial layer includes a thermally decomposable polymer.

18. The method of depositing the film of claim 17, wherein the forming of the polymer sacrificial layer includes:
depositing a precursor for forming the polymer sacrificial layer on the substrate to form a preliminary polymer sacrificial layer on the first surface and the second surface; and
removing a portion of the preliminary polymer sacrificial layer formed on the second surface by heat treatment.

19. The method of depositing the film of claim 18, wherein a thickness of a portion of the preliminary polymer sacrificial layer formed on the first surface is thicker than a thickness of the portion of the preliminary polymer sacrificial layer formed on the second surface.

20. A method of depositing a film comprising:
providing a substrate that includes a first surface including —OH or —NHx functional groups, and a second surface adjacent to the first surface and including no functional group or fewer —OH or —NHx functional groups than the first surface;
forming a polymer sacrificial layer including a thermally decomposable polymer on the first surface by using a molecular layer deposition (MLD) process;
forming a first film on the second surface; and
removing the polymer sacrificial layer formed on the first surface,
wherein the forming of the polymer sacrificial layer includes:
depositing a precursor for forming the polymer sacrificial layer on the substrate to form a preliminary polymer sacrificial layer on the first surface and the second surface; and
removing a portion of the preliminary polymer sacrificial layer formed on the second surface by heat treatment, and
wherein the precursor includes an electrophile and a compound that reacts with the electrophile to form the thermally decomposable polymer.
